(19) United States
(12) Patent Application Publication
(10) Pub. No.: US 2020/0230782 A1
(43) Pub. Date: Jul. 23, 2020

(54) Method and Apparatus for cleaning a substrate

(71) Applicant: APPLIED MATERIALS, INC., Santa Clara, CA (US)

(72) Inventors: Pulkit AGARWAL, Santa Clara, CA (US); Bonnie T. CHIA, Sunnyvale, CA (US); Song-Moon SUH, San Jose, CA (US); Cheng-Hsiung TSAI, Cupertino, CA (US); Dhritiman Subha KASHYAP, Bangalore (IN); Xiaoxiong YUAN, San Jose, CA (US); Eric RIESKE, Livermore, CA (US)

(21) Appl. No.: 16/838,848

(22) Filed: Apr. 2, 2020

Related U.S. Application Data
(63) Continuation of application No. 14/749,209, filed on Jun. 24, 2015.
(60) Provisional application No. 62/153,785, filed on Apr. 28, 2015.

(51) Int. Cl. B24C 1/00; B24C 3/32; H01L 21/67

(52) U.S. Cl. CPC B24C 1/003; H01L 21/67028; B24C 3/322

(57) ABSTRACT

Embodiments of methods and apparatus for cleaning contaminants from a substrate are disclosed herein. In some embodiments, a substrate cleaning apparatus includes: a substrate support to support a substrate along an edge of the substrate, wherein the substrate further includes a first side and an opposing second side having contaminants disposed on the second side; a showerhead disposed a first distance of about 1.5 mm to about 4.4 mm opposite the substrate support and facing the first side of the substrate; and one or more nozzles disposed a second distance of about 1 inch to about 2 inches beneath the substrate support to discharge a mixture of solid and gaseous carbon dioxide toward the contaminants on the second side of the substrate, and wherein the one or more nozzles have an angle of about 20 to about 40 degrees.

### CROSS-REFERENCE TO RELATED APPLICATIONS

This application is a continuation of U.S. application Ser. No. 14/749,209, filed Jun. 24, 2015, which claims benefit of U.S. provisional patent application Ser. No. 62/153,785, filed Apr. 28, 2015, both of which are herein incorporated by reference in their entirety.

### FIELD

Embodiments of the present disclosure generally relate to semiconductor processing equipment.

### BACKGROUND

A semiconductor substrate is handled on the substrate edge and backside numerous times during the manufacturing process, for example during metal deposition, chemical vapor deposition, or etching processes. Such handling can cause contaminants to adhere to the backside of the substrate and travel from chamber to chamber, substrate to substrate, front-opening unified pod (FOUP) to FOUP, or process tool to process tool along with the substrate. These contaminants can migrate to the front side of the substrate, resulting in yield loss. Alternatively, the contaminants can cause the substrate to not lay flat on a substrate support in a process tool. For example, in a lithography step, the contaminants can undesirably cause a substrate to lay unevenly atop a support stage in a lithography tool beyond a working depth of field of the stepper lens.

Typical solutions to the problem have been to remove the contaminants through an in-production-line cleaning tool using wet chemicals, backside scrubbing, attempts to limit particle formation, and/or frequent cleaning of process tools. However, these steps only mitigate the yield loss and are costly in terms of equipment and consumables. For example, use of wet chemicals requires wet chemistry handling and disposal, and possible undesired damage to the backside of the substrate.

As such, the inventors have provided improved methods and apparatus for cleaning particle contamination from a substrate.

### SUMMARY

Embodiments of methods and apparatus for cleaning contaminants from a substrate are disclosed herein. In some embodiments, a substrate cleaning apparatus includes: a substrate support to support a substrate along an edge of the substrate, wherein the substrate further includes a first side and an opposing second side having contaminants disposed on the second side; a showerhead disposed a first distance of about 1.5 mm to about 4.4 mm opposite the substrate support and facing the first side of the substrate; and one or more nozzles disposed a second distance of about 1 inch to about 2 inches beneath the substrate support to discharge a mixture of solid and gaseous carbon dioxide toward the contaminants on the second side of the substrate, and wherein the one or more nozzles have an angle of about 20 to about 40 degrees

In some embodiments, a method of cleaning contaminants from a substrate disposed atop a substrate support member is provided. In some embodiments, a method of cleaning contaminants from a substrate includes: (a) directing a mixture of solid and gaseous carbon dioxide from one or more nozzles to the second side of the substrate to remove one or more contaminants from the contaminated second side of the substrate, wherein the one or more nozzles are coupled to a moveable arm and disposed a distance of about 1 inch to about 2 inches beneath the substrate support, and wherein the one or more nozzles have an angle of about 20 to about 40 degrees; and (b) directing a flow of gas from a showerhead toward the first side of the substrate, wherein the showerhead is disposed a distance of about 1.5 mm to about 4.4 mm opposite the substrate support.

In some embodiments, a method of cleaning contaminants from a substrate disposed atop a substrate support, wherein the substrate has a first side, an opposing contaminated second side and an edge between the first side and the second side, the method includes: (a) directing a mixture of solid and gaseous carbon dioxide from one or more nozzles to the second side of the substrate to remove one or more contaminants from the contaminated second side of the substrate, wherein the one or more nozzles are coupled to a moveable arm and disposed a distance of about 1 inch to about 2 inches beneath the substrate support, and wherein the one or more nozzles have an angle of about 20 to about 40 degrees; (b) directing a flow of gas at a flow rate of about 300 slm to about 500 slm from a showerhead toward the first side of the substrate while directing the mixture of solid and gaseous carbon dioxide to the second side of the substrate, wherein the showerhead is disposed a distance of about 1.5 mm to about 4.4 mm opposite the substrate support; (c) rotating the substrate while directing the mixture of solid and gaseous carbon dioxide to the contaminated second side of the substrate; (d) actuating the arm to move from a center of the rotating substrate to an outer edge of the rotating substrate while dispensing the mixture; and (e) heating the showerhead to a temperature of about 120 degrees Celsius to about 150 degrees Celsius while directing the flow of gas from the showerhead toward the first side of the substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart for a method of cleaning a substrate in accordance with some embodiments of the present disclosure.

FIG. 2 depicts a schematic view of a substrate cleaning apparatus in accordance with some embodiments of the present disclosure.

FIGS. 3A-3F depict a stationary substrate in various stages of cleaning in accordance with some embodiments of the present disclosure.

FIGS. 4A-4F depict a rotating substrate in various stages of cleaning in accordance with some embodiments of the present disclosure.

FIG. 5 depicts a depicts a cluster tool suitable for performing portions of the present disclosure in accordance with some embodiments of the present disclosure.

FIG. 6, depicts an isometric view of a substrate support comprising a rotatable plate circumscribing the substrate in accordance with some embodiments of the present disclosure.

FIG. 7 depicts a side cross-sectional view of a portion of a substrate cleaning apparatus in accordance with some embodiments of the present disclosure.

FIG. 8 depicts an isometric view of a substrate cleaning apparatus in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the disclosure provide improved methods and apparatus for cleaning a substrate. Embodiments of the present disclosure may advantageously allow for the removal of contamination accumulated on a substrate during the manufacturing process, such as while handling the substrate between process steps and while chucking the substrate inside a process chamber, which can limit or prevent contaminants from reaching the front-side of a substrate and causing yield loss. Embodiments of the present disclosure may advantageously allow for the removal of the contamination without the potential damage to the substrate associated with contact cleaning or wet cleaning. Embodiments of the present disclosure may be used on a wide variety of cleaning surfaces to obtain high particle removal plus very low addition of particles, for example, in display processing, silicon chip packaging, hard disk media cleaning, and optics manufacturing.

Embodiments of the disclosure provide an improved apparatus for cleaning a substrate. As described below, an apparatus for removing contaminants from a substrate includes a substrate support to support a substrate, a heated showerhead disposed opposite the substrate support and one or more nozzles disposed beneath the substrate support to discharge a mixture of solid and gaseous carbon dioxide toward the contaminants on the second side of the substrate. As described below, the inventors have observed that the distance, described below, between the heated showerhead and the substrate allows for effective heat transfer between the showerhead and the substrate. As a result, the showerhead advantageously heats that substrate to reduce or prevent condensation from forming on the substrate as a result of the cleaning process. In addition, the distance between the showerhead and the substrate, as well as a sufficient flowrate of gas from the showerhead, advantageously create a suitable gas velocity and pressure at the peripheral edge of the substrate to advantageously reduce or prevent contaminants removed from the second side of the substrate from migrating to the first side of the substrate. Furthermore, the inventors have observed that the distance, described below, between the one or more nozzles and the substrate and the nozzle angle, described below, can advantageously improve contaminant removal from the second side of the substrate.

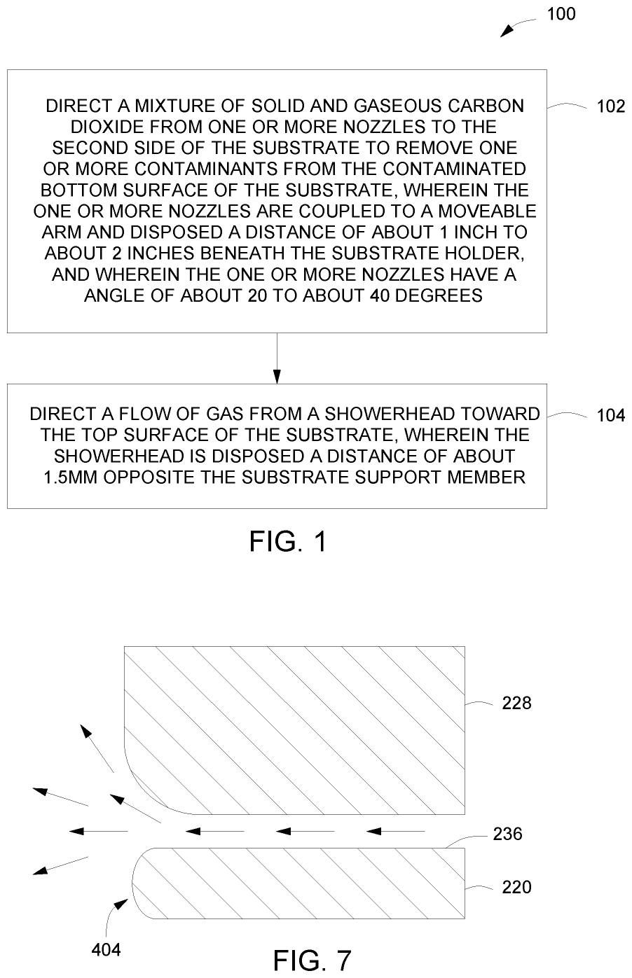

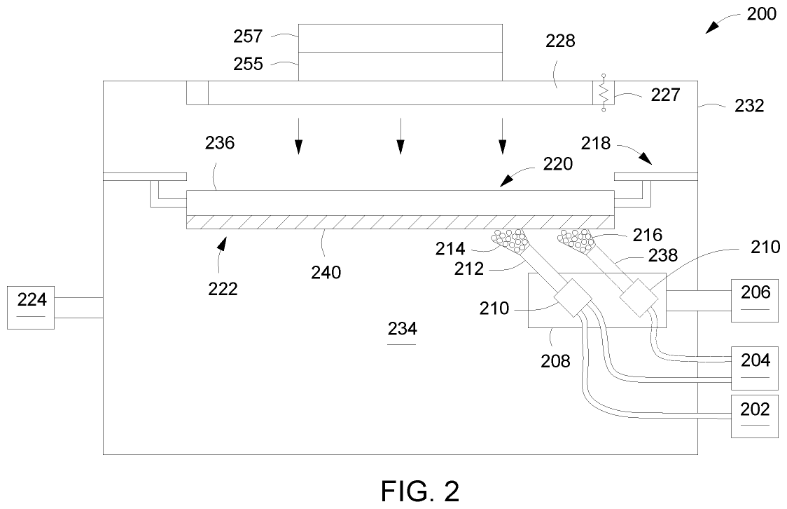

FIG. 1 depicts a flow chart for a method 100 of cleaning a substrate in accordance with some embodiments of the present disclosure. In some embodiments, at least some portions of the method 100 may be performed in a substrate cleaning apparatus, for example, such as the substrate cleaning apparatus 200 described below with respect to FIG. 2.

The particular embodiment of the substrate cleaning apparatus 200 shown herein is provided for illustrative purposes and should not be used to limit the scope of the disclosure. The substrate cleaning apparatus 200 depicted in FIG. 2 generally comprises a substrate support 218 to support a substrate 220. In some embodiments, the substrate support member is disposed within an optional process chamber 232 having a first volume 234. In other embodiments, the substrate support 218 may be disposed in any suitable location to support a substrate to be cleaned without being disposed in a chamber.

The substrate 220 may be any suitable substrate used in a semiconductor or similar thin-film manufacturing processes, such as circular, square, rectangular, or other shaped substrates of various materials. In some embodiments, the substrate 220 may be a semiconductor wafer (e.g., a 200 mm, 300 mm, 450 mm, or the like silicon wafer). The substrate 220 to be cleaned generally includes an uncontaminated first side 236 and a contaminated second side 222. In some embodiments, the substrate support 218 grips the substrate 220 by an outer edge of the substrate 220 without gripping the first side 236, in order to prevent contamination of the first side 236, and without gripping the second side 222, in order to allow full access to the second side 222 of the substrate 220.

Below the substrate 220 are one or more nozzles coupled to a moveable arm. For example, as depicted in FIG. 2, a first nozzle 212 is coupled to a moveable arm 208. The moveable arm 208 is coupled to an actuator 206 to facilitate movement of the moveable arm 208. In some embodiments, the first nozzle 212 is coupled to a liquid carbon dioxide source 202 (e.g., a first carbon dioxide source). The first nozzle 212 discharges a first mixture 214 comprising a stream of solid carbon dioxide entrained in a stream of gaseous carbon dioxide to the second side 222 of the substrate 220. In some embodiments, the liquid carbon dioxide passes through a fine mesh filter 210 (e.g., a nickel mesh filter) to advantageously remove gross particulates from the liquid carbon dioxide prior to discharge from the first nozzle 212. As used herein with respect to the mesh filter, “fine” refers to filter having a pore size that is smaller than about one-half the node size of a device being fabricated on the substrate. For example, in some embodiments where the node size is about 22 nm, the fine mesh filter 210 may have a filter pore size of less than about 11 nm.

In some embodiments, the one or more nozzles 212 are disposed a second distance beneath the substrate support. In some embodiments, the one or more nozzles are disposed about 1 to about 2 inches beneath the substrate support 218. In some embodiments, the one or more nozzles 212 are supported at an angle of about 20 to about 40 degrees from the substrate plane. The inventors have observed that a nozzle distance of about 1 to about 2 inches beneath the substrate support 218 and a nozzle angel of about 20 to about 40 degrees from the substrate 220 plane is optimal to remove contaminants from the second side 222 of the substrate 220.

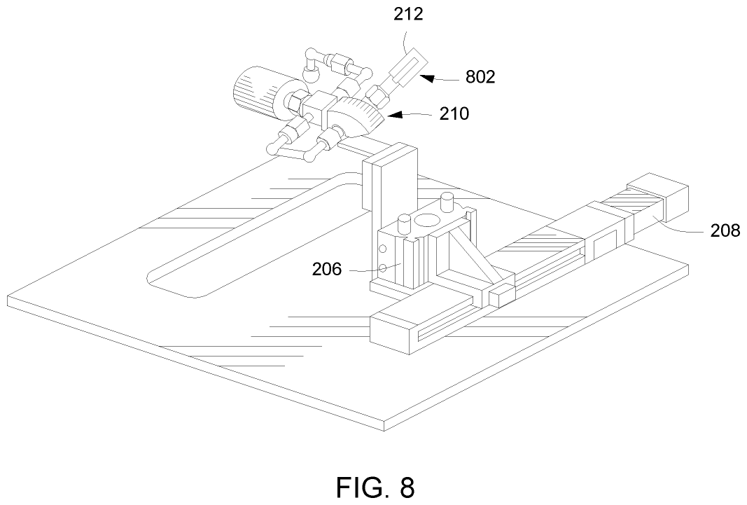

In some embodiments, an outer surface of each of the one or more nozzles (e.g., 212, 238, 300, 302) is covered by a heating element 802. In some embodiments, as depicted in FIG. 8, the heating element 802 may be a suitable heating element to prevent condensation at the outlet of the one or more nozzles (e.g., 212, 238, 300, 302). In some embodiments, the heating element 802 is maintained at a temperature of about 30 to about 40 degrees Celsius.

Application of the first mixture to the contaminated second side 222 removes contaminants 240 from the second side 222. In some embodiments, the liquid carbon dioxide is supplied to the first nozzle 212 at a pressure of about 200 to about 1000 psi, or in some embodiments, about 800 to about 850 psi. In some embodiments, the liquid carbon dioxide is supplied to the first nozzle 212 at a pressure dependent upon the vapor pressure of liquid CO₂ at room temperature (e.g., about 25 degrees Celsius). In some embodiments, the first nozzle 212 is a throttling nozzle, which causes an isenthalpic expansion of the liquid carbon dioxide, such that when the carbon dioxide exits the first nozzle 212, the liquid carbon dioxide expands into the first mixture 214. In some embodiments, the first mixture 214 comprises about 30% to about 40% solid carbon dioxide and about 60% to about 70% gaseous carbon dioxide.

Without wishing to be bound by theory, the inventors believe that the solid carbon dioxide particles strike the contaminants 240 on the second side 222 and change from the solid phase to the gas phase, resulting in an expansion which pushes the contaminants 240 off of the second side 222. However, other physical, chemical, and/or thermal processes that cause the removal of the contaminants 240 are possible.

In some embodiments, the first nozzle 212 is coupled to a gaseous carbon dioxide source 204 (e.g., a second carbon dioxide source), and discharges a second mixture comprising a stream of solid carbon dioxide entrained in a stream of gaseous carbon dioxide to the second side 222 of the substrate 220. A switch or other plumbing may be provided to selectively couple the first nozzle 212 to the liquid carbon dioxide source 202 or the gaseous carbon dioxide source 204. In some embodiments, the gaseous carbon dioxide passes through the fine mesh filter 210 (e.g., nickel mesh filter) as described above, to advantageously remove gross particulates from the gaseous carbon dioxide prior to discharge from the first nozzle 212.

Alternatively, in some embodiments, either the gaseous carbon dioxide source 204 or the liquid carbon dioxide source 202 is coupled to a second nozzle 238 which discharges the second mixture 216 to the second side 222 of the substrate 220. In some embodiments, the second nozzle is coupled to the moveable arm 208. In some embodiments, the gaseous carbon dioxide passes through a fine mesh filter 210 (e.g., nickel mesh filter) before being discharged by the second nozzle 238.

Similar to the first nozzle 212, in some embodiments, the second nozzle 238 is a throttling nozzle which causes an expansion of the gaseous carbon dioxide, such that when the gaseous carbon dioxide exits the second nozzle 238, the gaseous carbon dioxide expands into the second mixture 216. However, the second mixture 216 contains lesser solid carbon dioxide particles, in size as well as in amount, than the first mixture 214. In some embodiments, the second mixture 216 comprises about 1% to about 20% solid carbon dioxide and about 99% to about 80% gaseous carbon dioxide.

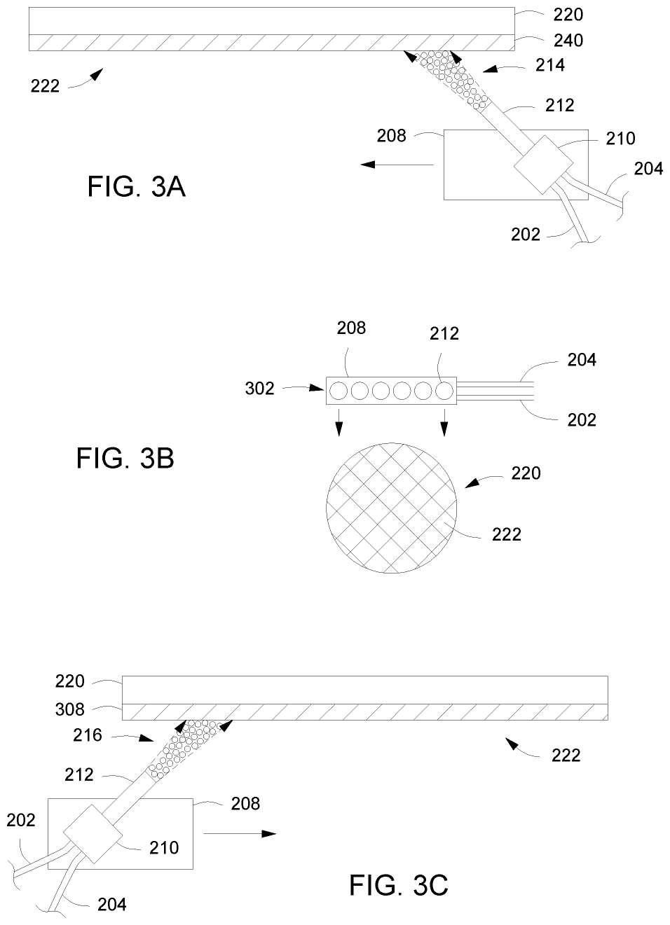

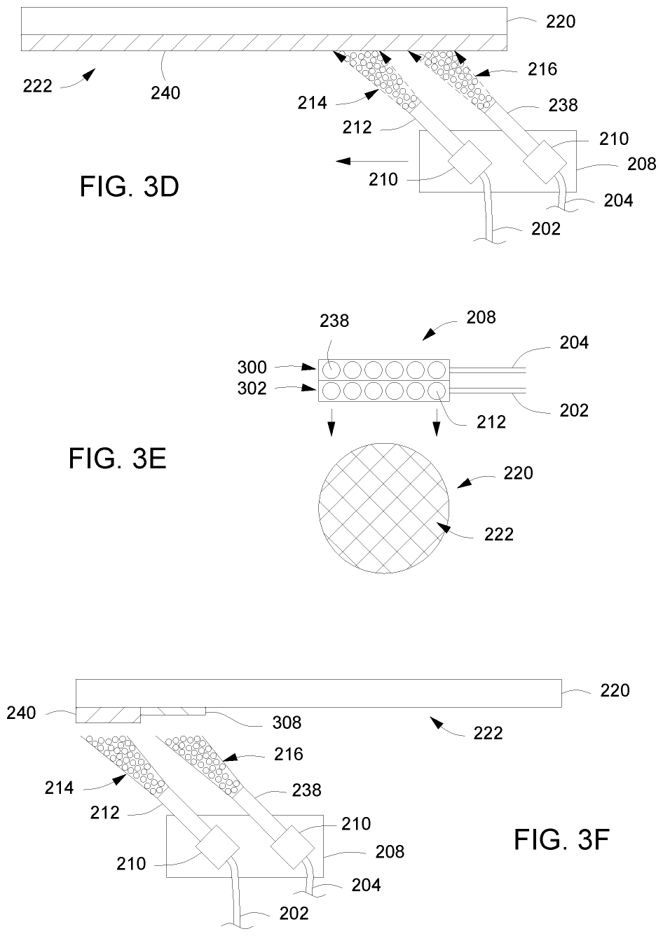

In some embodiments, as depicted in FIGS. 3A-3F, the substrate 220 is held in a stationary position by the substrate support 218. In some embodiments where the substrate 220 is held in a stationary position, as depicted in FIGS. 3A-30, a plurality of first nozzles 212 forms an array of first nozzles 302 coupled to a moveable arm 208 which traverses the diameter of the substrate 220. In some embodiments, the moveable arm 208 traverses the diameter of the substrate 220 at about 5 to about 15 cm/second. In some embodiments, the array of first nozzles 302 is arranged linearly along the length of the moveable arm 208. In some embodiments, the array of first nozzles 302 is arranged non-linearly along the length of the moveable arm 208. As the moveable arm 208 traverses the diameter of the substrate 220, the array of first nozzles 302 dispenses the first mixture 214 over the entire surface area of the second side 222 to remove contaminants 240. In some embodiments, once the contaminants 240 have been removed, or substantially removed, the array of first nozzles 302 dispenses the second mixture 216 over the entire surface area of the second side 222, for example, to remove at least some residue 308 left by the first mixture 214.

In some embodiments where the substrate 220 is held in a stationary position, as depicted in FIGS. 3D-3F, a plurality of first nozzles 212 forms an array of first nozzles 302 and a plurality of second nozzles 238 forms an array of second nozzles 300. In some embodiments, the array of first nozzles 302 and the array of second nozzles 300 are coupled to a moveable arm 208 which traverses the diameter of the substrate 220. In some embodiments, the array of first nozzles 302 is arranged linearly along the length of the moveable arm 208 and the array of second nozzles 300 is arranged linearly along the length of the moveable arm 208, parallel to the array of first nozzles 302. In some embodiments, the array of first nozzles 302 and the array of second nozzles 300 are arranged non-linearly along the length of the moveable arm 208. As the moveable arm 208 traverses the diameter of the substrate 220, the array of first nozzles 302 dispenses the first mixture 214 over the entire surface area of the second side 222 to remove contaminants 240 caused during substrate processing, while the array of second nozzles 300 dispenses the second mixture 216 over the entire surface area of the second side 222 to remove at least some of any residue 308 left by the first mixture 214.

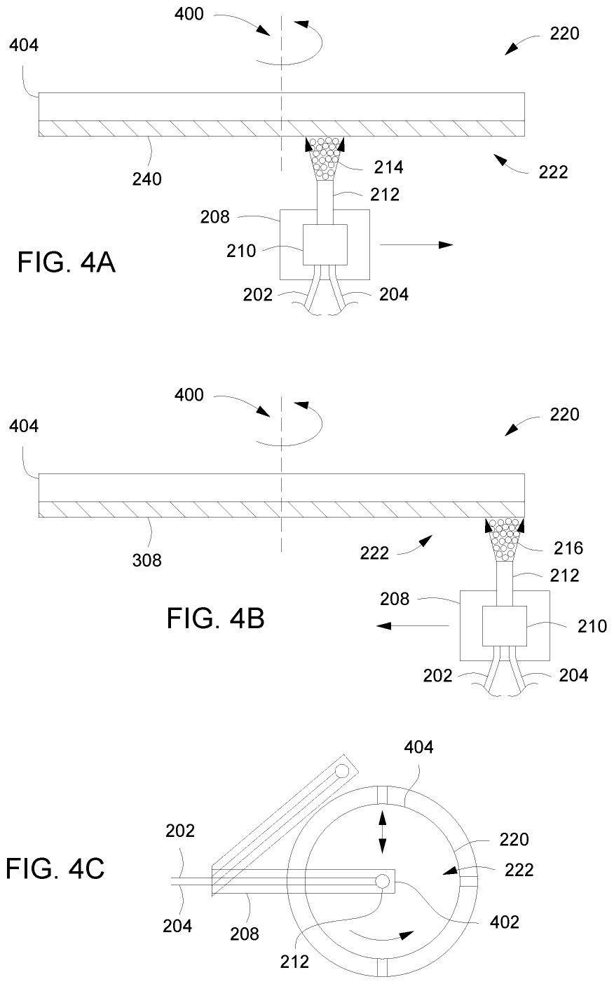

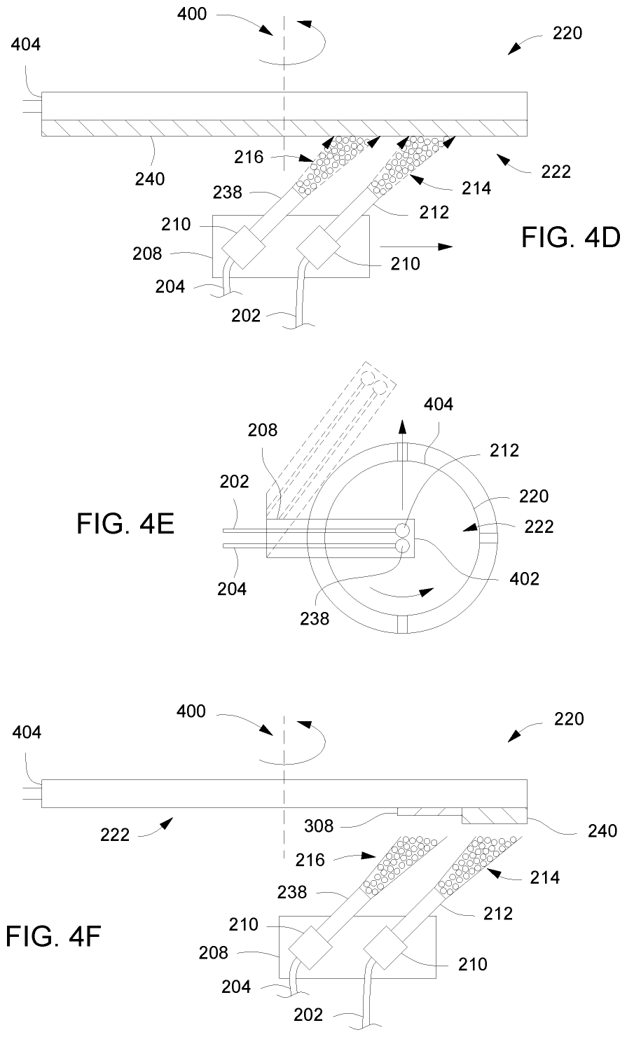

In some embodiments, as depicted in FIGS. 4A-4F, the substrate support 218 rotates the substrate 220 about a central axis 400. In some embodiments where the substrate 220 rotates as depicted in FIGS. 4A-4C, the first nozzle 212 is coupled to the moveable arm 208 at a first end 402 which is disposed over the central axis 400 of the substrate 220. As the substrate 220 rotates, the moveable arm 208 traverses, for example substantially linearly, from the central axis 400 of the substrate 220 to an outer edge 404 of the substrate 220. As the moveable arm 208 moves toward the outer edge 404 of the substrate 220 the first nozzle 212 dispenses a first mixture 214 onto the second side 222 of the substrate 220 to remove contaminants 240 deposited during substrate processing. Once the contaminants 240 have been removed, or substantially removed, the moveable arm 208 moves toward the central axis 400 of the substrate 220 as the first nozzle 302 dispenses the second mixture 216 over the entire surface area of the second side 222 to remove at least some of the residue 308 left by the first mixture 214.

In some embodiments, as depicted in FIGS. 4D-4F, a first nozzle 212 and a second nozzle 238 are coupled to the moveable arm 208 at a first end 402 which is disposed over the central axis 400 of the substrate 220. As the substrate 220 rotates, the moveable arm 208 traverses, for example substantially linearly, from the central axis 400 of the substrate 220 to an outer edge 404 of the substrate 220. As the moveable arm 208 moves toward the outer edge 404 of the substrate 220 the first nozzle 212 dispenses a first mixture 214 onto the second side 222 of the substrate 220 to remove contaminants 240 deposited during substrate processing, while the second nozzle 238 dispenses the second mixture 216 over the second side 222 to remove at least some of any residue 308 deposited by the first mixture 214. In some embodiments, as the moveable arm 208 moves toward the outer edge 404 of the substrate 220 the first nozzle 212 dispenses a first mixture 214 onto the second side 222 of the substrate 220 to remove contaminants 240 deposited during substrate processing and as the moveable arm 208 moves toward the central axis 400 of the substrate 220 the second nozzle 238 dispenses the second mixture 216 over the second side 222 to remove residue 308 deposited by the first mixture 214. The above examples of substrate supports, nozzle configurations, and the relative movement between the substrate supports and the nozzles, are illustrative only and other configurations may be utilized to perform the cleaning process as described herein.

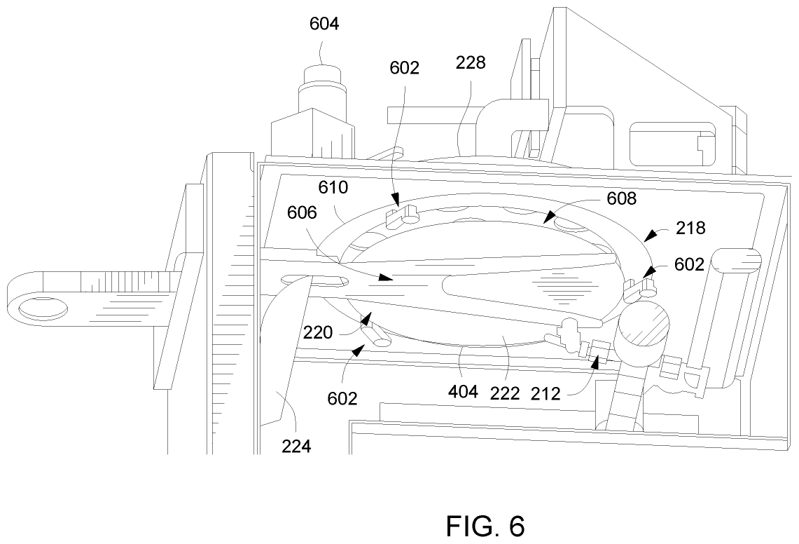

In one embodiment, as depicted in FIG. 6, a substrate support 218 comprises a rotatable plate 610 circumscribing the substrate 220. In some embodiments, the rotatable plate 610 rotates the substrate 220 about a central axis 400 at about 0.8 to about 2 rotations per second (RPS). The rotatable plate 610 comprises a central opening 608 allowing the mixture 214, 216 to contact the second side 222 of the substrate 220. In some embodiments, the diameter of the showerhead 228 is the same as or substantially the same as the diameter of the central opening 608. A plurality of gripping elements 602 coupled to the rotatable plate 610 grips an outer edge 404 of the substrate 220. Gripping an outer edge 404 of the substrate 220 advantageously exposes the entire contaminated second side 222 of the substrate 220 to the cleaning process. In some embodiments, the plurality of gripping elements 602 comprises at least 3 gripping elements. In some embodiments, the plurality of gripping elements 602 comprises a plurality of wafer clips. In some embodiments, the plurality of gripping elements 602 are coupled to an actuator 604 to allow the gripping elements 602 to grip the substrate from the transfer arm 606 during the cleaning process and release the substrate 220 to the transfer arm 606 at the completion of the cleaning process. The transfer arm 606 transfers the substrate 220 to the gripping elements 602 and retracts to allow the mixture 214, 216 to clean contaminants from the entire second side 222 of the substrate. Once the cleaning process is complete, the transfer arm 606 extends beneath the substrate 220 and receives the substrate 220 from the gripping elements 602.

In some embodiments, a showerhead 228 directs a flow of gas toward the first side 236 of the substrate 220. In some embodiments, the first gas may be air or nitrogen gas (N₂). The showerhead 228 is disposed a first distance opposite the substrate support 218 and facing the first side of the substrate 220. The first distance is about 1.5 mm to about 4.4 mm. In some embodiments, a filter 255 is fluidly coupled to the showerhead 228 to remove contaminants from the gas. In some embodiments, a fan 257 is fluidly coupled to the filter 255 to direct a gas to the showerhead 228. In some embodiments, the gas is air or an inert gas, such as argon or helium. In some embodiments, the gas flow rate through the showerhead 228 is about 300 slm to about 500 slm. In some embodiments, a heater 227 is coupled to the showerhead 228 to heat the showerhead 228 to a temperature of about 120 to about 150 degrees Celsius. In some embodiments, the heater 227 may be an electric coil wrapped around the showerhead 228 or embedded in the showerhead 228. In some embodiments, the showerhead 228 is heated to a temperature of about 120 to about 150 degrees Celsius.

The inventors have observed that directing the mixtures 214, 216 of solid and gaseous carbon dioxide, which are typically at a temperature of about −40 degrees Celsius, toward the contaminated second side 222 of the substrate 220 results in localized condensation within the area contacted by the mixture 214, 216. The inventors have observed that a distance of about 1.5 mm to about 4.4 mm between the showerhead 228 and the substrate support 218 and a showerhead 228 temperature of about 120 to about 150 degrees Celsius heats the substrate 220 to about a temperature of about 80 to about 100 degrees Celsius. The inventors have observed that a substrate temperature of about 80 to about 100 degrees Celsius eliminates the localized condensation in areas contacted by the mixtures 214, 216.

In some embodiments, as depicted in FIG. 7, the gas flows around the outer edges 404 of the substrate 220 to advantageously limit or prevent loosened contamination particles and particles from the first mixture 214 and second mixture 216 from contaminating the first side 236 of the substrate 220. The inventors have observed that a distance of about 1.5 mm to about 4.4 mm between the showerhead 228 and the substrate 106 and a gas flow rate of about 300 slm to about 500 slm provide a gas flow of sufficient velocity and pressure at the outer edge 404 of the substrate 220 to prevent contaminants from migrating to the first side 236 of the substrate 220.

In some embodiments, the process chamber 232 comprises an exhaust system 224, fluidly coupled to the first volume 234, to remove loose contaminants and carbon dioxide particles from the first volume 234. In some embodiments, the exhaust system 224 is disposed in the direction of the mixture flow to avoid recirculation and provide flow toward the exhaust. In some embodiments, the exhaust pressure is about 0.3 to about 0.5 atm.

FIG. 1 depicts one exemplary method 100 of cleaning a substrate 220 using the substrate cleaning apparatus 200 described above. In the method 100, a substrate 220 that has been processed through a typical substrate manufacturing process, such as chemical vapor deposition or etching, and has a layer of contamination on the second side 222 of the substrate is placed upon the substrate support 218. The substrate is transferred by the transfer arm 606 to the substrate support 218, where gripping elements 602 hold the substrate 220 by the outer edge 404. The transfer arm 606 is retracted from underneath the substrate to provide access to the entire contaminated second side 222 of the substrate.

At 102, a mixture of solid and gaseous carbon dioxide is directed from one or more nozzles (e.g., 212, 238, 300, 302), toward the contaminated second side 222 of the substrate 220. The one or more nozzles (e.g., 212, 238, 300, 302) are disposed a second distance of about 1 inch to about 2 inches beneath the substrate support and at an angle of about 20 to about 40 degrees from the substrate plane. At 104, a flow of gas from the showerhead is directed toward the first side 236 of the substrate 220 while directing at least one of the first mixture 214 or second mixture 216 of solid and gaseous carbon dioxide to the second side 222 of the substrate 220. As discussed above, the showerhead is disposed a distance of about 1.5 mm to about 4.4 mm opposite the substrate support and is heated to a temperature of about 120 to about 150 degrees Celsius. Following completion of the cleaning process, the transfer arm 606 is extended underneath the substrate 220 to receive the substrate 220 from the gripping elements 602.

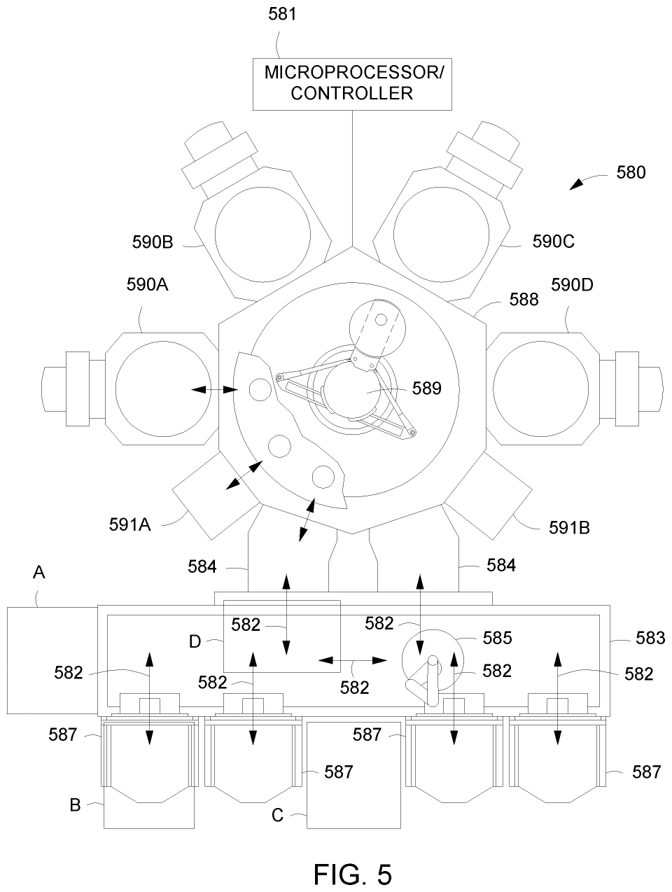

FIG. 5 depicts a cluster tool suitable for performing portions of the present disclosure. Generally, the cluster tool is a modular system comprising multiple chambers (e.g., process chambers 590A-D, service chambers 591A-B, or the like) which perform various functions including substrate cleaning, substrate center-finding and orientation, degassing, annealing, deposition and/or etching. According to embodiments of the present disclosure, the cluster tool may include at least a substrate cleaning apparatus, as described above, configured to perform the method of cleaning a substrate as described above. Integrating the substrate cleaning apparatus with the cluster tool advantageously prevents cross-contamination from chamber to chamber by performing the cleaning process after every manufacturing step. The multiple chambers of the cluster tool are mounted to a central transfer chamber which houses a robot adapted to shuttle substrates between the chambers. The transfer chamber is typically maintained at a vacuum condition and provides an intermediate stage for shuttling substrates from one chamber to another and/or to a load lock chamber positioned at a front end of the cluster tool.

By way of illustration, a particular cluster tool 580 is shown in a plan view in FIG. 5. The cluster tool 580 generally comprises a plurality of chambers and robots and is preferably equipped with a microprocessor controller 581 programmed to carry out the various processing methods performed in the cluster tool 580. A front-end environment 583 is shown positioned in selective communication with a pair of load lock chambers (load locks 584). A pod loader 585 disposed in the front-end environment 583 is capable of linear and rotational movement (arrows 582) to shuttle cassettes of substrates between the load locks 584 and a plurality of pods 587 which are mounted on the front-end environment 583. The load locks 584 provide a first vacuum interface between the front-end environment 583 and a transfer chamber 588. Two load locks 584 are provided to increase throughput by alternatively communicating with the transfer chamber 588 and the front-end environment 583. Thus, while one load lock 584 communicates with the transfer chamber 588, a second load lock 584 communicates with the front-end environment 583. A robot 589 is centrally disposed in the transfer chamber 588 to transfer substrates from the load locks 584 to one of the various processing chambers 590A-D and service chambers 591A-B.

In some embodiments the exemplary method 100 of cleaning contaminants from a substrate, as described above, may be performed in connection with processing the substrate within at least one of the processing chambers. For example, at least one of the processing chambers (for example, any of 590A-D) may be a plasma etch chamber or other process chamber that performs a process on a substrate leading to contaminants begin disposed on the backside of the substrate necessitating removal. Accordingly, for example, following an etch or other process, the substrate may be removed from the plasma etch chamber and transported to the substrate cleaning chamber by the robot 589 and the pod loader 585 to remove contamination caused during the etch process. By providing a cleaning apparatus coupled to the same cluster tool as the process chambers processing the substrate, the substrate may be cleaned as soon as possible after processing to advantageously minimize contact of the contaminated substrate with processing equipment and migration of the contamination to other components or substrates as well as potentially damaging the substrate or other substrates.

The cleaning apparatus may be located in any of a number of locations on the cluster tool 580. For example, the cleaning apparatus may be disposed on a side of the factory interface, or front-end environment 583, as depicted by dashed box A. Alternatively or in combination a cleaning apparatus may be coupled to or disposed in place of one of the pods 587 coupled to the front-end environment 583, as depicted by dashed box B. Alternatively or in combination a cleaning apparatus may be coupled to or disposed at a central portion of the front-end environment 583, opposite the load locks 584, as depicted by dashed box C. Alternatively or in combination a cleaning apparatus may be coupled to or disposed along an upper surface of the front-end environment 583, as depicted by dashed box D. In positions A-C, the cleaning apparatus may or may not be disposed in a chamber. In position D, the cleaning apparatus may be provided with no chamber and may be configured to clean substrates as they move past the cleaning apparatus between pods 587 and the load locks 584. Other locations or configurations of the cleaning apparatus may also be used.

Thus, improved methods and apparatus for cleaning a substrate have been disclosed herein. The inventive apparatus may advantageously allow for the removal of contamination accumulated on a substrate during the manufacturing process, such as during handling the substrate between process steps and while chucking the substrate inside a process chamber to prevent contaminants from reaching the front-side of a substrate and causing yield loss.

While the foregoing is directed to embodiments of the present disclosure, other and further embodiments of the disclosure may be devised without departing from the basic scope thereof.

1. An apparatus for removing contaminants from a substrate, comprising:
a substrate support to support a substrate along an edge of the substrate, wherein the substrate further includes a substrate plane, a first side and an opposing second side having contaminants disposed on the second side;
a showerhead disposed a first distance of about 1.5 mm to about 4.4 mm opposite the substrate support and facing the first side of the substrate; and
one or more nozzles disposed a second distance of about 1 inch to about 2 inches beneath the substrate support and configured to discharge a mixture of solid and gaseous carbon dioxide toward the contaminants on the second side of the substrate, wherein the one or more nozzles have an angle of about 20 to about 40 degrees from the substrate plane.

2. The apparatus of claim 1, further comprising a filter fluidly coupled to the showerhead.

3. The apparatus of claim 2, further comprising a fan fluidly coupled to the filter to direct a gas to the showerhead.

4. The apparatus of claim 1, further comprising a heater coupled to the showerhead.

5. The apparatus of claim 4, wherein the heater is configured to heat the showerhead to a temperature of about 120 to about 150 degrees Celsius.

6. The apparatus of claim 1, wherein the substrate support comprises a plurality of gripping elements.

7. The apparatus of claim 6, further comprising an actuator coupled to the plurality of gripping elements.

8. The apparatus of claim 1, wherein the substrate support is configured to rotate the substrate.

9. The apparatus of claim 1, wherein the one or more nozzles are further configured to discharge a mixture of solid and gaseous carbon dioxide comprising about 30% to about 40% solid carbon dioxide and about 60% to about 70% gaseous carbon dioxide.

10. The apparatus of claim 1, further comprising a heater covering an outer surface of the one or more nozzles.

11. The apparatus of claim 1, further comprising a filter coupled to the one or more nozzles.

12. The apparatus of claim 1, wherein the one or more nozzles are coupled to a moveable arm configured to move the one or more nozzles from a center of the substrate to an outer edge of the substrate.

13. The apparatus of claim 12, further comprising an actuator coupled to the moveable arm.

14. The apparatus of claim 1, further comprising a process chamber having a first volume, wherein the substrate support is disposed within the first volume.

15. The apparatus of claim 14, further comprising an opening in the process chamber to exhaust contaminants from the first volume.

16. An apparatus for removing contaminants from a substrate, comprising:
a substrate support to support a substrate along an edge of the substrate, wherein the substrate further includes a substrate plane, a first side, and an opposing second side having contaminants disposed on the second side;
a showerhead disposed a first distance of about 1.5 mm to about 4.4 mm opposite the substrate support and facing the first side of the substrate; and
one or more nozzles disposed a second distance of about 1 inch to about 2 inches beneath the substrate support in fluid communication with a source comprising liquid carbon dioxide, wherein the one or more nozzles have an angle of about 20 to about 40 degrees from the substrate plane.

17. An apparatus for removing contaminants from a substrate, comprising:
a substrate support to support a substrate along an edge of the substrate, wherein the substrate further includes a substrate plane, a first side, and an opposing second side having contaminants disposed on the second side;
a showerhead disposed a first distance of about 1.5 mm to about 4.4 mm opposite the substrate support and facing the first side of the substrate; and
one or more nozzles disposed a second distance of about 1 inch to about 2 inches beneath the substrate support configured to discharge a mixture of liquid carbon dioxide and carbon dioxide particles, wherein the one or more nozzles have an angle of 20 to 40 degrees from the substrate plane, and wherein the showerhead is configured to be heated to a temperature of about 120 to about 150 degrees Celsius to heat the substrate to a temperature of about 80 to about 100 degrees Celsius.

18. The apparatus for removing contaminants from a substrate of claim 17, wherein the one or more nozzles are coupled to a moveable arm configured to move the one or more nozzles from a center of the substrate to an outer edge of the substrate.

19. The apparatus of claim 17, further comprising a heater covering an outer surface of the one or more nozzles configured to heat the outer surface of the one or more nozzles to a temperature of about 30 to about 40 degrees Celsius.

20. The apparatus of claim 17, wherein the showerhead is configured for a gas flow rate of about 300 standard liter per minute (slm) to about 500 slm to prevent contaminants disposed on a second side of the substrate from migrating to the first side of the substrate.
